(19) United States
(12) Patent Application Publication
(10) Pub. No.: US 2020/0321250 A1
(43) Pub. Date: Oct. 8, 2020

(54) WET CHEMICAL DIE SINGULATION SYSTEMS AND RELATED METHODS

(71) Applicant: SEMICONDUCTOR COMPONENTS INDUSTRIES, LLC, Phoenix, AZ (US)

(72) Inventor: Michael J. SEDDON, Gilbert, AZ (US)

(73) Assignee: SEMICONDUCTOR COMPONENTS INDUSTRIES, LLC, Phoenix, AZ (US)

(21) Appl. No.: 16/713,725

(22) Filed: Dec. 13, 2019

Related U.S. Application Data
(60) Provisional application No. 62/827,976, filed on Apr. 2, 2019.

(51) Int. Cl. H01L 21/78; H01L 21/683; H01L 21/308; H01L 21/306

(52) U.S. Cl. CPC H01L 21/78; H01L 21/6836; H01L 2221/68327; H01L 21/30604; H01L 21/308

(57) ABSTRACT

Implementations of methods for singulating die from a wafer may include: providing a semiconductor wafer having a first side and a second side. The first side may include a plurality of die and a plurality of die streets between each of the plurality of die. The method may include applying a mask over the plurality of die and around the plurality of die streets. The method may also include wet etching through the semiconductor wafer at the plurality of die streets to singulate the plurality of die.

### CROSS REFERENCE TO RELATED APPLICATIONS

This application claims the benefit of the filing date of U.S. Provisional Patent Application 62/827,976, entitled “WET CHEMICAL DIE SINGULATION SYSTEMS AND RELATED METHODS” to Seddon, which was filed on Apr. 2, 2019, the disclosure of which is hereby incorporated entirely herein by reference.

### BACKGROUND

### 1. Technical Field

Aspects of this document relate generally to die singulation systems and methods. More specific implementations involve methods of wet chemical etching.

### 2. Background

Semiconductor devices include integrated circuits found in common electrical and electronic devices, such as phones, desktops, tablets, other computing devices, and other electronic devices. The devices are separated through singulating a wafer of semiconducting material into a plurality of semiconductor die. Upon singulation, the die can be mounted on a package and electrically integrated with the package which may then be used in the electrical or electronic device.

### SUMMARY

Implementations of methods for singulating die from a wafer may include: providing a semiconductor wafer having a first side and a second side. The first side may include a plurality of die and a plurality of die streets between each of the plurality of die. The method may include applying a mask over the plurality of die and around the plurality of die streets. The method may also include wet etching through the semiconductor wafer at the plurality of die streets to singulate the plurality of die.

Implementations of methods for singulating die from a wafer may include one, all, or any of the following:

The semiconductor wafer may have a thickness of 25 microns to 50 microns.

The wet etching comprises applying an etchant to one of the first side of the wafer and the second side of the wafer.

The method may also include mounting the semiconductor wafer to a picking tape.

The method may also include mounting the wafer to a carrier.

Wet etching may include one of submerging the semiconductor wafer into an etchant bath, spraying the semiconductor wafer with an etchant, or puddling the etchant onto the semiconductor wafer.

The mask may be temporarily present or sacrificially removed.

The method may also include regulating a rate of the wet etching by controlling a temperature of an etchant.

Implementations of methods for singulating die from a wafer may include: providing a semiconductor wafer having a first side and a second side. The first side may include a plurality of die and a plurality of die streets between each of the plurality of die. The wafer may have a thickness of 10 microns to 50 microns. The method may include coupling the semiconductor wafer to a tape wherein the tape is coupled with a film frame. The method may include applying a mask over the plurality of die and around the plurality of streets. The method may include only wet etching through the semiconductor wafer at the plurality of die streets to singulate the plurality of die.

Implementations of methods for singulating die from a wafer may include one, all, or any of the following:

The method may also include singulating the plurality of die through jet ablation.

The wet etching may include applying an etchant to one of the first side of the wafer and the second side of the wafer.

The wet etching may include one of submerging the semiconductor wafer into an etchant bath, spraying the semiconductor wafer with an etchant, and puddling the etchant onto the semiconductor wafer.

The mask may be temporarily present or sacrificially removed.

The method may further include regulating a rate of the wet etching by controlling a temperature of an etchant.

Implementations of methods for singulating die from a wafer may include: providing a semiconductor substrate having a first side and a second side and a thickness between the first side and the second side. The first side may include a plurality of die and a plurality of die streets between each of the plurality of die. The method may include coupling a back metal to the second side of the semiconductor wafer and applying a mask over the plurality of die and around the plurality of streets. The method may include wet etching through the thickness at the plurality of die streets. The wafer may have a thickness of 10 microns to 100 microns.

Implementations of methods for singulating die from a wafer may include one, all, or any of the following:

The method may include singulating the plurality of die through jet ablation.

The wet etching may include applying an etchant to one of the first side of the wafer and the second side of the wafer.

Wet etching may include one of submerging the semiconductor wafer into an etchant bath, spraying the semiconductor wafer with an etchant, and puddling the etchant onto the semiconductor wafer.

The method may also include removing the mask during wet etching.

The method may further include wet etching the back metal.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side view of an implementation of a wafer with a plurality of semiconductor die formed thereon/therein;

FIG. 2 is a side view of an implementation of a wafer coupled to an implementation of a tape on an implementation of a film carrier;

FIG. 3 is a side view of an implementation of a wafer coupled to an implementation of a carrier coupled to an implementation of a vacuum chuck;

FIG. 4 is a side view of an implementation of a wafer having an implementation of a mask applied on a first side of the implementation of the wafer;

FIG. 5 is a side view of an implementation of a wafer having an implementation of a mask applied on a second side of the implementation of the wafer;

FIG. 6 is a side view of an implementation of a wafer having an implementation of a back metal on a second side of the implementation of the wafer;

FIG. 7 is a side view of an implementation of a wafer coupled to an implementation of a film frame, the wafer having an implementation of a mask applied to a back metal on a second side of the wafer;

FIG. 8 is a side view of an implementation of a wafer after etching through a back metal on a second side of the wafer;

FIG. 9 is side view of an implementation of a plurality of die on an implementation of a film frame;

FIG. 10 is a side view of an implementation of a wafer having an implementation of a mask applied over a plurality of die and the wafer is coupled to an implementation of a film frame;

FIG. 11 is a side view of an implementation of a plurality of die having an implementation of a mask applied and the plurality of die are coupled to an implementation of a film frame;

FIG. 12 is a side view of an implementation of a wafer having an implementation of a mask applied and the wafer is coupled to an implementation of a film frame;

FIG. 13 is a side view of an implementation of a plurality of die on an implementation of a film frame after singulation;

FIG. 14 is a side view of an implementation of a wafer having the plurality of die streets pre-cut by a saw;

FIG. 15 is a side view of an implementation of a plurality of die on an implementation of a film frame after singulation;

FIG. 16 is a side view of an implementation of a wafer having the plurality of die streets pre-cut by an implementation of an etching tool;

FIG. 17 is a side view of an implementation of a wafer during an implementation of a plasma etching method;

FIG. 18 is a side view of an implementation of a wafer during an implementation of a stealth etching method;

FIG. 19 is a side view of an implementation of a plurality of die on an implementation of a film frame after singulation;

FIG. 20 is a side view of an implementation of a wafer in an implementation of an etch bath;

FIG. 21 is a side view of an implementation of a wafer having an implementation of etching chemistry sprayed onto the wafer;

FIG. 22 is a side view of an implementation of a wafer being spun on a vacuum chuck;

FIG. 23 is a side view of an implementation of a wafer having an implementation of an edge ring;

FIG. 24 is a side view of an implementation of a wafer having an implementation of an edge ring after singulation; and

FIG. 25 is a side view of an implementation of two die after singulation using wet etching.

### DESCRIPTION

This disclosure, its aspects and implementations, are not limited to the specific components, assembly procedures or method elements disclosed herein. Many additional components, assembly procedures and/or method elements known in the art consistent with the intended wet etch singulation systems will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such wet etch singulation systems, and implementing components and methods, consistent with the intended operation and methods.

Due to the miniaturization of packages, and the need for increased efficiencies in MOSFET devices, the typical die thickness for new devices is continually decreasing. New technologies are continually being developed for about 25-50 um thick dies to meet the industry requirements. A die singulation process which is optimal for about 10-100 um thick wafers may meet the requirements for the majority of new technologies.

For semiconductor die that are less than about 50 microns in thickness, particular processing challenges exist. Die handling, die strength, and performing processing operations with the die all present specific challenges, as die and wafer breakage can significantly reduce yield and/or affect device reliability. Die strength is negatively affected by traditional singulation options like sawing which induce die chipping and cracking along the die streets. These chips and cracks formed during the sawing process can eventually propagate during operation and reliability testing causing the die to fail. The method described herein may be used with narrow saw streets and may offer stronger die strengths. In various implementations, an entire wafer may be singulated at one time. In other implementations, multiple wafers may be singulated at one time.

Referring to FIG. 1, a side view of a substrate 2 including die 4 on a first side 6 of the substrate is illustrated. The substrate 2 also includes a plurality of die streets 8 between each of the plurality of die. The term “substrate” refers to a semiconductor substrate as a semiconductor substrate is a common type of substrate, however, “substrate” is not an exclusive term that is used to refer to all semiconductor substrate types. Similarly, the term “substrate,” may refer to a wafer as a wafer is a common type of substrate, however, “substrate” is not an exclusive term that is used to refer to all wafers. The various semiconductor substrate types disclosed in this document that may be utilized in various implementations may be, by non-limiting example, round, rounded, square, rectangular, or any other closed shape. In various implementations, the substrate 2 may include a substrate material such as, by non-limiting example, single crystal silicon, silicon dioxide, glass, gallium arsenide, sapphire, ruby, silicon on insulator, silicon carbide, polycrystalline or amorphous forms of any of the foregoing, and any other substrate material useful for constructing semiconductor devices. In particular implementations, the substrate may be a silicon-on-insulator substrate.

While the methods disclosed herein are focused on singulating the substrate 2, it is understood that the substrate 2 may include and/or be coupled to other elements not illustrated, such as a plurality of semiconductor devices. Also, while the term “wafer” is used to describe many of the semiconductors being processed using methods disclosed herein, the methods may also be applied to substrates. In such implementations, the plurality of semiconductor devices may include a power device or non-power semiconductor device. In implementations where a plurality of power devices are coupled to the substrate, the power devices may include, by non-limiting example, a metal oxide field effect transistor (MOSFET), an insulated gate bipolar transistor (IGBT), a diode, a thyristor, a silicon controlled rectifier (SCR), or any other kind of power semiconductor device.

Referring still to FIG. 1, a method for singulating die from a wafer using wet etching may include providing a semiconductor wafer having a first side and a second side. On the first side, the semiconductor wafer may include a plurality of die and a plurality of die streets/die grids/scribe lines between each of the plurality of die. In various implementations, the wafer 2 is thinned. In particular implementations, the substrate 2 may be about 25 microns, less than 30 micrometers (um) thick, and/or less than 50 um thick. In other implementations, the substrate may be about 8 um thick. In some implementations, the substrate may be about 10-100 um thick. The method may include applying a mask over the plurality of die and around the plurality of streets. The method may also include wet etching through the semiconductor wafer at the plurality of die streets to singulate the plurality of die. In some implementation of the method, only wet etching may be used to singulate the plurality of die. In other implementations, the die streets may be pre-cut or pre-etched using, by non-limiting example, saws, lasers, stealth etching, scribing, plasma etching, or other methods for removing semiconductor material between die on a wafer/substrate.

In FIG. 1, the die are illustrated on either side of the die street 8. In various implementations, the die may include aluminum, copper, and other electrically conductive materials. Following the completion of the fabrication process (or during some portion of it, in some implementations), the semiconductor substrate 2 may be thinned on a side of the semiconductor substrate 2 that is opposite the side on which the one or more semiconductor devices have been formed to a desired substrate thickness. The thinning process takes place using backgrinding, lapping, chemical etching, any combination thereof, or any other technique for removing the material of the semiconductor substrate 2 substantially uniformly across the largest planar surface of the substrate.

In various implementations, the substrate 2 may be thinned to an average thickness less than 50 μm. In other implementations, the substrate 2 may be thinned to an average thickness less than 30 μm. In still other implementations, the substrate 2 may be thinned to an average thickness less than 100 μm, more than 100 μm, and in other various implementations, the substrate 2 may not be thinned. In particular implementations, the substrate 2 may be thinned to an average thickness of 25 μm, and in other particular implementations, the substrate may be thinned to an average thickness of 75 μm. As used herein, the average thickness is the thickness measured across at least a majority of the substrate's or wafer's largest planar surface. The substrate 2 may be thinned through backgrinding, etching, or any other thinning technique. In various implementations, the wafer scribe ID can be protected so that it does not etch and the wafer ID will remain after singulation.

In various implementations, the thinning process may create an edge ring around the wafer (like that present in the backgrinding process marketed under the tradename TAIKO by Disco Hi-Tec America, Inc. of Santa Clara, Calif.). The edge ring acts to structurally support the wafer following thinning so that no wafer carrier may need to be utilized during subsequent processing steps. In various implementations, the thinning process may be carried out after the semiconductor substrate 2 has been mounted to a backgrinding tape whether an edge ring is formed during backgrinding or not. A wide variety of backgrinding tapes may be employed in various implementations, including those that are compatible with subsequent etching operations.

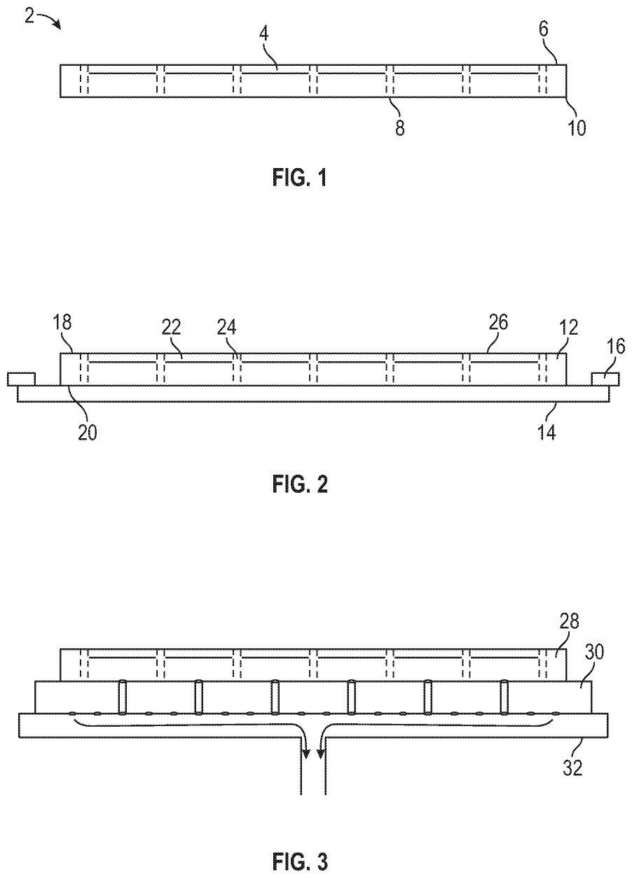

Referring to FIG. 2, an implementation of a wafer 12 coupled to a tape 14 coupled to a film frame 16 is illustrated. In various implementations, the tape may be a pick and place tape. In some implementations, the film frame may be an acid resistant material. By non-limiting example, the film frame may be made from polyphenylene sulfide, styrene acrylonitrile, polyethylene terephthalate glycol (PETG), black conductive polystyrene, and other hard plastics. As illustrated in FIG. 2, the first side of the wafer 18 includes a plurality of die 22 and a plurality of die streets 24 between each of the plurality of die 22. An implementation of a method for singulating a plurality of die 22 from a wafer 12 may include providing a semiconductor wafer 12 having a first side 18 and a second side 20. The method may also include applying a mask over the plurality of die and around the plurality of streets. The plurality of die may be singulated through only wet etching through the semiconductor wafer at the plurality of die streets. In various implementations the wet etching chemicals may include buffered hydrofluoric acid (BHF) or other etching acids. Various concentrations of hydrofluoride (HF), nitric acid (HNO₃), phosphoric acid (H₃PO₄), and sulfuric acid (H₂SO₄). By non-limiting example a ratio of 2:2:1:1 (HF:HNO₃:H₃PO₄:H₂SO₄) may be used or for a slower etch the ratio may include 1:1:8 (HF:HNO₃:H₂SO₄). In some implementations, a single acid can be used. In other implementations, more than one acid can be used in a single wet etch process. In various implementations, the mask may be a sacrificial mask, an organic mask, or other masks that are removed during the etching process. In other implementations, the mask may be a hard material used in the semiconductor wafer manufacturing process such as, by non-limiting example, a passivation layer or a metallization layers.

Referring to FIG. 3, a wafer 28 is illustrated mounted to a carrier 30. In various implementation, the method may further include mounting the wafer to a carrier. The carrier may be mounted onto a vacuum chuck 32. In various implementations, the wafer can also be on a temporary carrier where a vacuum is applied under each die so that once the etching and rinsing process has been completed the dies can easily be removed from the hard carrier instead of from an adhesive tape.

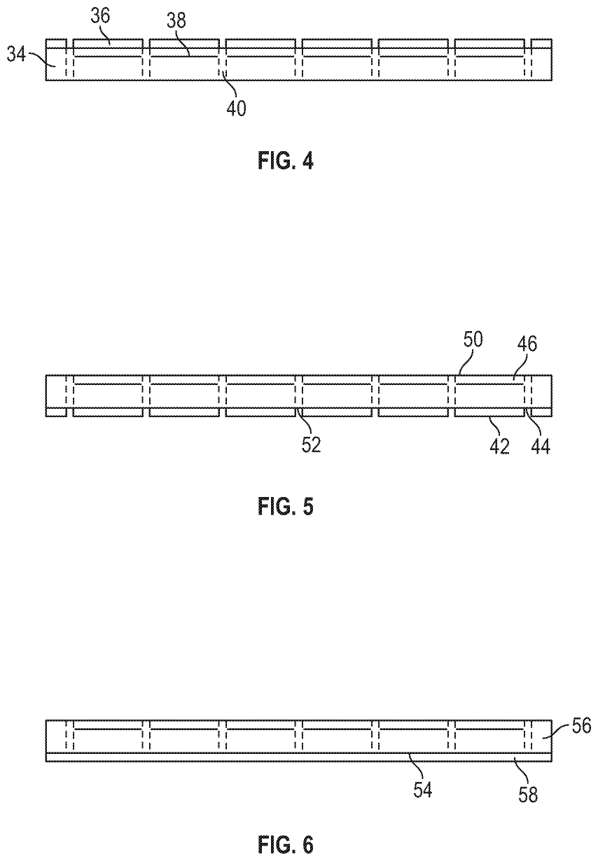

Referring to FIG. 4, a wafer 34 having a mask 36 patterned over a plurality of die 38 is illustrated. The mask 36 is patterned around a plurality of die streets 40. The method of singulating die may include applying a mask over the plurality of die and around the plurality of die streets. In various implementations, the wafer may be patterned with a photoresist on the front side of the wafer. In other implementations, a photoresist may be patterned on a second side or back side of the wafer. In some implementations, the mask may be a temporary mask. In still other implementations, the masking layer may be sacrificial and removed or partially removed during the etching process. In various implementations, the wet etching chemicals may include the same chemicals used for wafer thinning.

Referring to FIG. 5, an implementation of a wafer 41 having a mask layer 42 on the second side 44 of the wafer 41 is illustrated. The mask 42 is patterned on the side opposite the die 46 on the first side 50 of the wafer 44. The mask 42 is patterned around the die streets 52. In this particular implementation, the wet chemical etching is done on the second side of the wafer. As previously described in other implementations, wet etching of wafers may also be done from the first side of the wafer. In various implementations of a method of singulating die from a wafer, a mask may be patterned on the first side of the wafer or the second side of the wafer. In some implementations, the etching tool used in the methods described herein may have built in end point detection. Built in end point detection may allow for more control of the etching process.

Referring to FIGS. 6-9, an implementation for singulating die on a wafer having a back metal/backside metal layer is illustrated. Referring to FIG. 6, a second side 54 of the substrate 56 may be coupled to a back metal layer 58. In various implementations, a back metal layer 58 may be applied to the semiconductor substrate 56 through, by non-limiting example, sputtering, evaporation, plating, or another metal deposition process. The back metal layer may include, by non-limiting example, copper, aluminum, nickel, any other metal, any alloy thereof, and any combination thereof. In various implementations, the substrate 56 may be directly coupled to the back metal layer 58. In other implementations (though not illustrated), other layers, such as a metal seed layer and/or adhesion layer, may be coupled between the metal layer and the substrate 56. In still other implementations, rather than a plurality of layers, the back metal layer may be the only layer coupled over the substrate 56. In various implementations of a method of singulating die from a wafer, the wafer may be patterned by etch resistant backmetal such as solderable metal capped with gold on the second side of the wafer.

In various implementations, the back metal layer may be about 10 μm thick. In other implementations, the backside metal layer may be more or less thick than 10 μm. The backside metal layer 58 may be evaporated onto the substrate 56, however, in other implementations (including implementations having thicker substrates), the back metal layer 58 may be plated onto the substrate 56 or formed on the substrate using another metal coupling technique such as adhering/bonding a metal foil to the substrate.

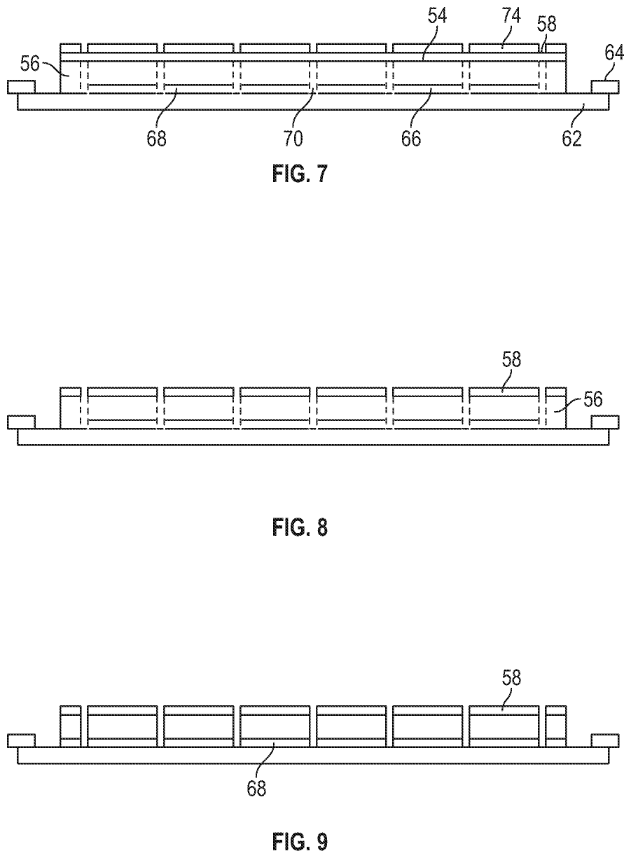

Referring to FIG. 7, the wafer 56 is illustrated on a tape 62 coupled with a film frame 64. Implementations of the method may include coupling the first side 66 of the wafer 56 to the tape 62. A plurality of die 68 separated by a plurality of die streets 70 are on the first side 66 of the wafer. A back metal 58 is coupled to a second side 54 of the wafer. The back metal is then patterned with a photoresist material 74. In other implementations, jet ablation may be used in combination with wet etching when a back metal is included on the wafer to singulate the back metal after wet etching. Referring to FIG. 8, the wafer 56 is shown after etching through the back metal 58.

Referring to FIG. 9, a plurality of die are illustrated after singulation. The plurality of die 68 each include a back metal 58. In various implementations, the mask may be a sacrificial mask that is removed as part of the etching process. In other implementations, the mask may be partially or fully removed during the singulation. In still other implementations, the method may include removing the mask after singulation of the plurality of die through a rinsing/plasma ashing process. The singulated die may then be picked from the tape. In some implementations, the singulated die may be re-mounted to another tape and picked from that tape.

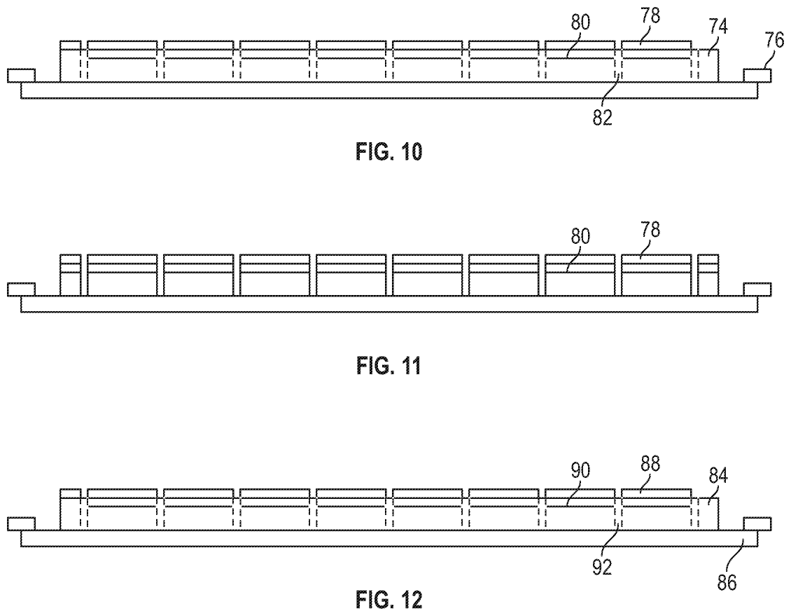

Referring to FIG. 10-11, another implementation of a method of singulating a plurality of die using wet etching is illustrated. In FIG. 10, a wafer 74 mounted to a film frame 76 is illustrated. The wafer 74 includes a patterned mask 78 over the plurality of die 80 and around/adjacent the die streets 82 between the plurality of die 80. The method includes etching through the die streets 82 by applying an etchant to the first side of the wafer 74. In various implementations, the rate of singulating by etching may be regulated by controlling the temperature of the etchant. The rate of etching can also be controlled by spiking the etch chemistry with hydrofluoric acid (HF) as the HF is consumed during the etching process. Small amounts of HF can be added to the etch chemistry at a set interval based on the amount of Si that has been etched. The HF may also be added when a sensor in the etch chemistry detects the need to add more HF. Spiking or adding more HF allows the etching process to be done for an extended period of time. Spiking the etch chemistry also allows etching process to occur more quickly. Now referring to FIG. 11, the plurality of die 80 are illustrated after singulation. The method further includes removing the mask material. In various implementations, the mask may be removed through rinsing or plasma ashing. The plurality of die may than be removed from the tape using any method described herein.

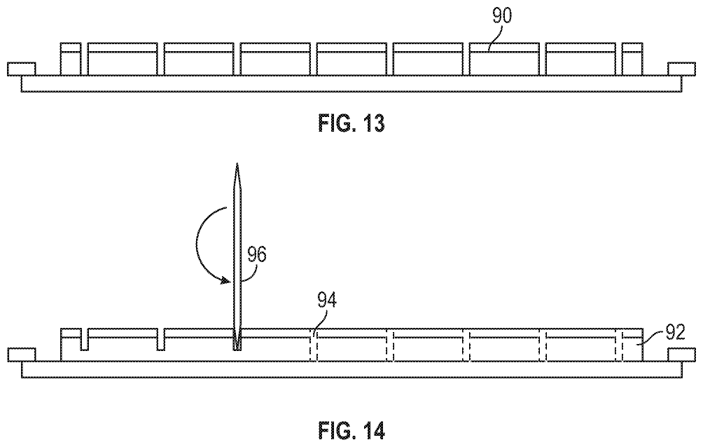

Referring to FIG. 12-13, another variation on implementations of a method for singulating die is illustrated. In FIG. 12, a wafer 84 is illustrated coupled to a tape. A mask 88 is illustrated coupled over the plurality of die 90 and around the plurality of streets 92. The mask may include a temporary etch resistive material which degrades during etching of the die streets. By non-limiting example, the mask may include an oxide or organic material that is removed during etching. In various implementations, a method for singulating the die may include using the metallization and passivation layers on the wafer as a hard mask for the etching process. Referring to FIG. 13, the plurality of die 90 are illustrated after etching with the mask material having been removed during etching.

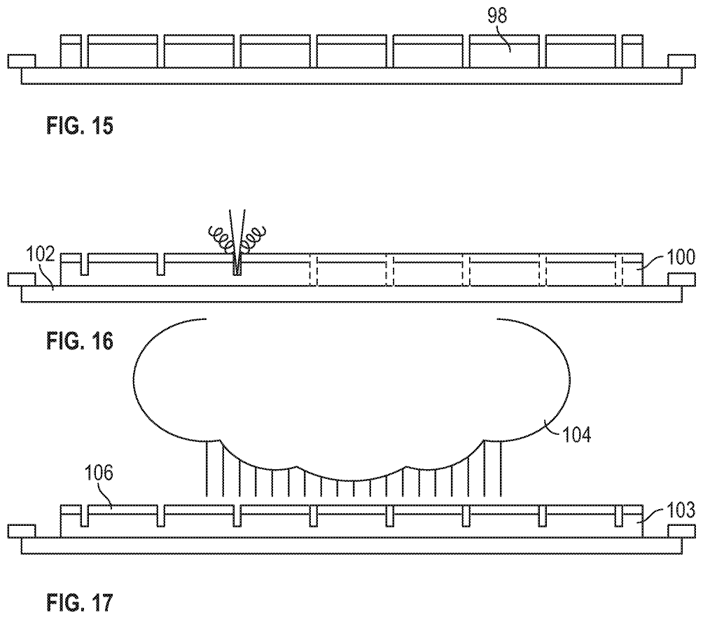

Referring to FIG. 14, an implementation of a method of singulating die using wet etching is illustrated where the method includes pre-cutting die streets 94 using a saw 96 is illustrated. In various implementations, pre-cutting may be used to further speed up/control the process of singulating the die through wet chemical etching. Pre-cutting may be used for wafers that have a thickness between about 10-100 microns. In various implementations, pre-cutting may also be used for substrates having a thickness between about 25-50 microns. Pre-cutting may also assist with cutting through the back metal layer to prepare the wafer for subsequent wet etching using the back metal as the masking layer. Referring to FIG. 15, the plurality of die 98 are illustrated after singulation through wet etching following the pre-cutting. In other implementations, precutting may also be used on the front side of the wafer (not shown) to remove passivation or metallization from the saw street before the wet etch singulation process begins.

Referring to FIG. 16, a wafer 100 coupled with a tape 102 is illustrated. Here, the method includes pre-cutting the wafer 100 using a laser scribe or jet ablation to start a partial etch of the wafer. As illustrated, the pre-cutting singulates the back metal on the wafer allowing the back metal to act as a masking material for the wet etching process. The method then includes wet chemical etching to fully singulate the plurality of die from the wafer. Referring to FIG. 17, an implementation of a wafer 103 during plasma etching 104 is illustrated. In various implementations of a method of singulating a plurality of die 106, a partial plasma etch may be performed prior to the wet chemical etch of the die streets. The plasma etch may be employed in situations where there is no back metal on the back of the wafer or after the back metal has already been singulated using any of the method disclosed by this document.

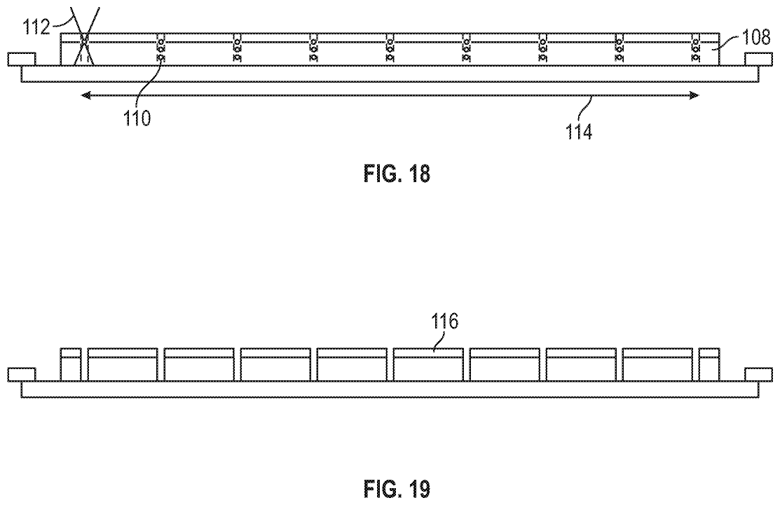

Referring to FIGS. 18-19, an implementation of a method using stealth dicing in combination with wet etching is illustrated. In FIG. 18, an implementation of a silicon wafer 108 is illustrated. The method of die singulation includes stealth dicing involving focusing a laser in each of the die streets to form a damaged region in the die street. The wafer 108 is then stretched 114 using a tape expander to break the die apart from each other along the damaged regions. In some implementations, the die may be partially singulated/damaged using stealth dicing and the remaining material needed to singulate the die may then be wet etched from the die street. In such implementations, the use of a tape expander may not be used. Referring to FIG. 19, the plurality of die 116 are illustrated after the singulation process has been completed.

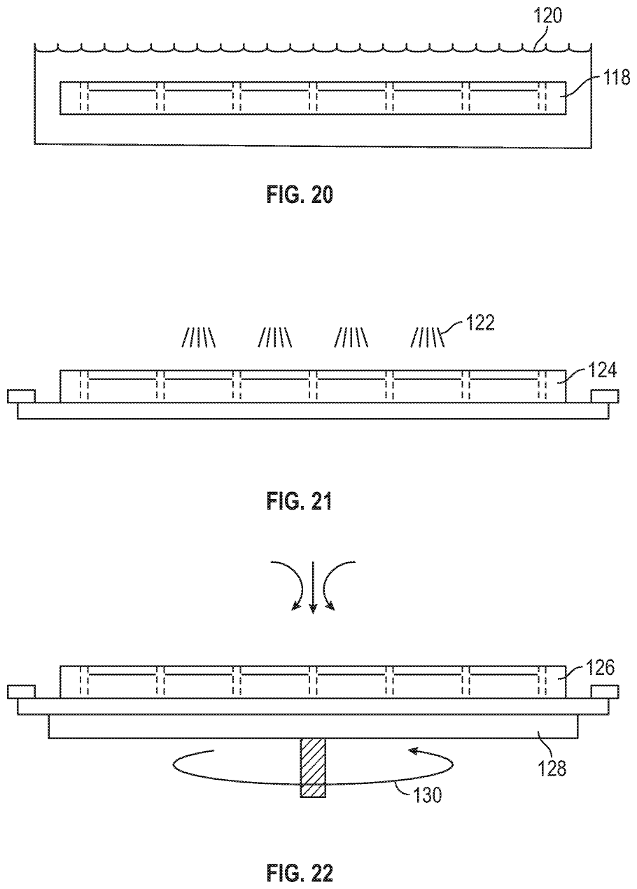

By non-limiting example, the wet etching disclosed in this document may be performed by various methods, including, by non-limiting example, submerging the semiconductor wafer into an etchant bath, spraying the semiconductor wafer with an etchant, puddling the etchant onto the semiconductor wafer, or any combination thereof. Referring to FIG. 20, an example of a wafer 118 submerged in an etchant bath 120 is illustrated. This method of applying the etchant to the wafer may be used with a standalone wafer, cassette of wafers, or wafer or cassette of wafers coupled to a tape and a film frame. Submerging the wafer may also be used with any pre-cutting method of singulating a plurality of die from a wafer having a thickness between about 10-100 microns. Referring to FIG. 21, an example of spraying an etchant 122 on a semiconductor wafer 124 is illustrated. As illustrated, the wafer 124 is coupled to a tape. In various implementations, the tape is a pick and place tape. In other implementations, other suitable tapes may be used. In various implementations, the wafer may be coupled to a chuck during spraying. Referring to FIG. 22, an example of a wafer 126 coupled to a chuck 128 that is rotating 130 is illustrated. While the chuck is rotating the etchant may be sprayed, poured, or puddled onto the wafer to singulate a plurality die from the wafer. The rotation process may be in one direction, various alternating directions, include periods of no movement followed by rotation of the wafer, any many other possible combinations.

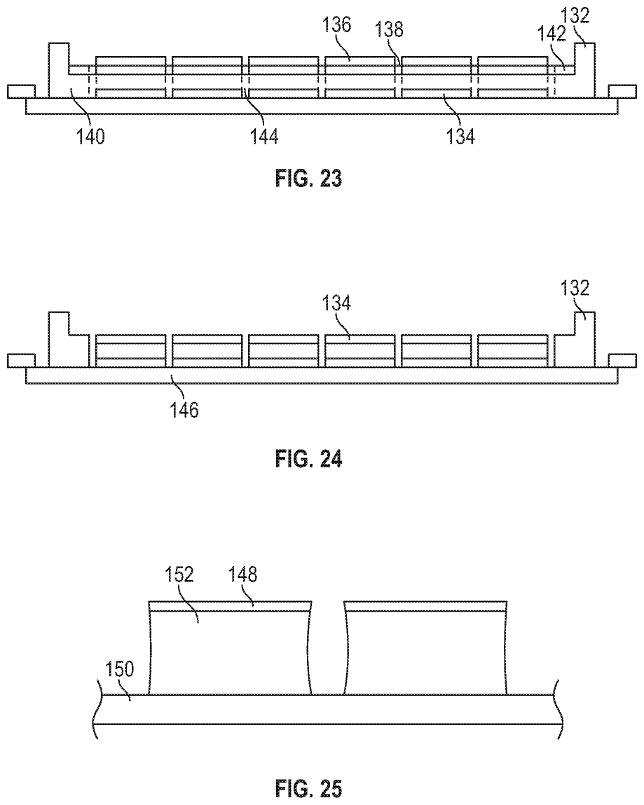

Referring to FIGS. 23-24, an implementation of a method of singulating a plurality of die from a wafer having an edge ring is illustrated. As described above, the edge ring 132 may be formed during the thinning process using a grinding process like a Taiko grinding process. In various implementations, the wafer may be thinned to a thickness of less than 39 microns. In some implementations, the wafer may have a thickness as small as about 10 microns. The method for singulating the plurality of die 134 may include applying a mask 136 on a second side 138 of the wafer 140 opposite the plurality of die 134 on the first side of the wafer. The mask may include a patterned photoresist in various implementations. The mask may be applied to a back metal layer 142 on the second side of the wafer. In various implementations, the mask may be sacrificial and be removed as part of the etching process. In some implementations, the mask may include a metal layer or a passivation layer that is already included as part of the wafer. In some implementations, the mask may be the back metal layer itself. The method then includes etching through the plurality of die streets 144 between the plurality of die 134 by applying an etchant to the wafer. In various implementations, the wet chemical etchant may include more than one acid or any other wet etchant disclosed in this document. The speed of singulation may be controlled by controlling the temperature of the wet etchant. In various implementations, the etchant may be applied through submerging the wafer in etchant, by spraying etchant on the wafer, or by pooling the etchant on the wafer or any other etching method disclosed in this document. Referring to FIG. 24, the plurality of die 134 are shown after singulation through applying wet etchant. The edge ring 132 is also singulated from the die during the etching process. The plurality of die may be then picked directly from the tape 146 or transferred to another tape.

Referring to FIG. 25, a close up view of an implementation of two die 148 after singulation by wet etching is illustrated. The die 148 are illustrated coupled to a pick and place tape 150. The die can be removed directly from this tape or may be transferred to another tape for further processing. As illustrated, the method of singulating a plurality of die through wet etching may give the walls 152 of the die a curved shape as a result of the isotropic characteristics of the wet etching process.

In places where the description above refers to particular implementations of wet chemical die singulation systems and implementing components, sub-components, methods and sub-methods, it should be readily apparent that a number of modifications may be made without departing from the spirit thereof and that these implementations, implementing components, sub-components, methods and sub-methods may be applied to other wet chemical die singulation systems.

What is claimed is:

1. A method for singulating die from a wafer comprising:
providing a semiconductor wafer comprising a first side and a second side, the first side comprising a plurality of die and a plurality of die streets between each of the plurality of die;
applying a mask over the plurality of die and around the plurality of streets;
only wet etching through the semiconductor wafer at the plurality of die streets to singulate the plurality of die.

2. The method of claim 1, wherein the semiconductor wafer has a thickness of 25 microns to 50 microns.

3. The method of claim 1, wherein the wet etching comprises applying an etchant to one of the first side of the wafer or the second side of the wafer.

4. The method of claim 1, further comprising mounting the semiconductor wafer to a picking tape.

5. The method of claim 1, further comprising mounting the wafer to a carrier.

6. The method of claim 1, wherein wet etching comprises one of submerging the semiconductor wafer into an etchant bath, spraying the semiconductor wafer with an etchant, or puddling the etchant onto the semiconductor wafer.

7. The method of claim 1, wherein the mask is one of temporarily present or sacrificially removed.

8. The method of claim 1, further comprising regulating a rate of the wet etching by controlling a temperature of an etchant.

9. A method for singulating die from a wafer comprising:
providing a semiconductor wafer comprising a first side and a second side, the first side comprising a plurality of die and a plurality of die streets between each of the plurality of die;
coupling the semiconductor wafer to a tape wherein the tape is coupled with a film frame;
applying a mask over the plurality of die and around the plurality of streets; and
only wet etching through the semiconductor wafer at the plurality of die streets to singulate the plurality of die;
wherein the wafer has a thickness of between 10 microns to 50 microns.

10. The method of claim 9, further comprising singulating the plurality of die through jet ablation.

11. The method of claim 9, wherein the wet etching comprises applying an etchant to one of the first side of the wafer or the second side of the wafer.

12. The method of claim 9, wherein wet etching comprises one of submerging the semiconductor wafer into an etchant bath, spraying the semiconductor wafer with an etchant, or puddling the etchant onto the semiconductor wafer.

13. The method of claim 9, wherein the mask is one of temporarily present or sacrificially removed.

14. The method of claim 9, further comprising regulating a rate of the wet etching by controlling a temperature of an etchant.

15. A method for singulating die from a wafer comprising:
providing a semiconductor substrate comprising a first side and a second side and a thickness between the first side and the second side, the first side comprising a plurality of die and a plurality of die streets between each of the plurality of die;
coupling a back metal to the second side of the semiconductor wafer;
applying a mask over the plurality of die and around the plurality of streets; and
wet etching through the thickness at the plurality of die streets;
wherein the wafer has a thickness of between 10 microns to 100 microns.

16. The method of claim 15, further comprising singulating the plurality of die through jet ablation.

17. The method of claim 15, wherein the wet etching comprises applying an etchant to one of the first side of the wafer or the second side of the wafer.

18. The method of claim 15, wherein wet etching comprises one of submerging the semiconductor wafer into an etchant bath, spraying the semiconductor wafer with an etchant, or puddling the etchant onto the semiconductor wafer.

19. The method of claim 15, further comprising removing the mask during wet etching.

20. The method of claim 15, further comprising wet etching the back metal.
